(19) United States
(12) Patent Application Publication
(10) Pub. No.: US 2021/0181715 A1
(43) Pub. Date: Jun. 17, 2021

(54) MANAGING APPARATUS

(71) Applicant: JUKI CORPORATION, Tokyo (JP)

(72) Inventor: Takahiko IMASU, Tama-shi (JP)

(21) Appl. No.: 17/186,743

(22) Filed: Feb. 26, 2021

Related U.S. Application Data
(62) Division of application No. 15/336,833, filed on Oct. 28, 2016.

(30) Foreign Application Priority Data
Oct. 30, 2015 (JP) 2015-214995

(51) Int. Cl. G05B 19/418; H05K 13/08

(52) U.S. Cl. CPC G05B 19/418; Y02P 90/02; G05B 2219/45031; H05K 13/0882

(57) ABSTRACT

A main management software equipped on a managing apparatus determines electronic components to be mounted by each electronic components mounting machine on the basis of information relating to a board to be manufactured; sends information relating to the electronic components to be mounted to at least one piece of sub-management software or the main management software itself that has, as a management target, the electronic components mounting machine to mount the electronic components; acquires information relating to preset items extracted from calculation results obtained using a manufacturing program for mounting the electronic components and sent from each of the sub-management software and the main management software itself; and adjusts the electronic components to be mounted by each electronic components mounting machine on the basis of the acquired information relating to the items and the information relating to the board to be manufactured.

### CROSS-REFERENCE TO RELATED APPLICATION

The present invention claims the benefit of priority of Japanese Patent Application No. 2015-214995 filed on Oct. 30, 2015, the disclosure of which is incorporated herein by reference.

### TECHNICAL FIELD

The present invention relates to a managing apparatus for managing electronic components mounting machines each of which moves electronic components held by nozzles and mounts them on boards.

### BACKGROUND ART

Electronic components mounting machines for mounting electronic components on boards are equipped with a head having nozzles and mount electronic components held by the nozzles on boards. In electronic components mounting machines, an electronic component existing in an electronic component supply device is absorbed by a nozzle of a head by moving the nozzle in the direction perpendicular to the surface of a board and then the head is moved relative to surface of the board in directions parallel with it. After the nozzle has arrived at a mounting position of the absorbed electronic component, the nozzle is brought close to the board by moving the nozzle in the direction perpendicular to the surface of the board and the electronic component is mounted on the board (refer to JP-A-2008-124169, for example).

In such electronic components mounting machines, mounting order of electronic components to be mounted on a board is set using a manufacturing program etc. and the electronic components are mounted on the board in the thus-set order.

On the other hand, in mounting systems for manufacturing boards, one board is manufactured by constructing a production line by plural electronic components mounting machines and causing them to mount electronic components at different sets of positions. There are mounting systems that are equipped with a managing apparatus for determining what electronic components mounting machines in a production line should be used to mount electronic components on a board.

Such managing apparatus manage electronic components mounting machines using management software. To enable management of electronic components mounting machines, management software needs to hold various kinds of information that are necessary for use of the electronic components mounting machines. These kinds of information need to be updated more frequently as the number of electronic components mounting machines to be managed using the management software increases. Furthermore, to develop management software capable of accommodating a variety of electronic components mounting machines, it is necessary to handle a vast amount of information, which takes long time.

### SUMMARY OF THE INVENTION

The present invention has been made in the above circumstances, and an object of the invention is therefore to provide a managing apparatus capable of developing or maintaining management software more simply and causing individual electronic components mounting machines to operate stably.

The invention provides a managing apparatus that manages plural electronic components mounting machines for mounting electronic components on a board, comprising main management software capable of managing at least one electronic components mounting machine; and at least one piece of sub-management software capable of managing at least one electronic components mounting machine that is not a management target of the main management software. The sub-management software acquires, from the main management software, information relating to electronic components to be mounted on a board by the electronic components mounting machine as a management target of the sub-management software, generates a manufacturing program on the basis of the acquired information, extracts information relating to preset items from calculation results obtained using the manufacturing program, and sends the extracted information to the main management software. The main management software determines electronic components to be mounted on the board by each of the electronic components mounting machines on the basis of information relating to a board to be manufactured; sends information relating to the electronic components to be mounted to the sub-management software or the main management software itself that has, as a management target, the electronic components mounting machine to mount the electronic components; acquires information relating to information relating to the items extracted from calculation results obtained using the manufacturing program for mounting the electronic components and sent from each of the sub-management software and the main management software itself; and adjusts the electronic components to be mounted by each of the electronic components mounting machines on the basis of the acquired information relating to the items and the information relating to the board to be manufactured.

It is preferable that the items include at least one of the number of feeders and a time relating to manufacture.

It is preferable that the sub-management software monitor production by its management target electronic components mounting machine, and send information extracted from the management target electronic components mounting machine to the main management software; and that the main management software monitor production by its management target electronic components mounting machine, and manage information extracted from the management target electronic components mounting machine and the information acquired from the sub-management software.

The invention provides advantages that management software can be developed and maintained more easily and stable operation of individual electronic components mounting machines is enabled.

### BRIEF DESCRIPTION OF THE DRAWINGS

FIG. 1 is a schematic diagram showing a general configuration of a mounting system;

FIG. 2 is a schematic diagram showing a general configuration of each electronic components mounting machine;

FIG. 3 is a flowchart illustrating an example operation of each electronic components mounting machine;

FIG. 4 is a flowchart illustrating an example operation of a managing apparatus; and

FIG. 5 is a flowchart illustrating another example operation of the managing apparatus.

### DETAILED DESCRIPTION

The present invention will be hereinafter described in detail with reference to the drawings. The invention is not limited to the following modes for carrying out the invention (hereinafter referred to as an embodiment). As for constituent elements of the following embodiment, the invention may employ corresponding ones that can be conceived easily by those skilled in the art, are substantially the same as them, or are equivalent to them. And constituent elements disclosed in the embodiment can be combined together as appropriate.

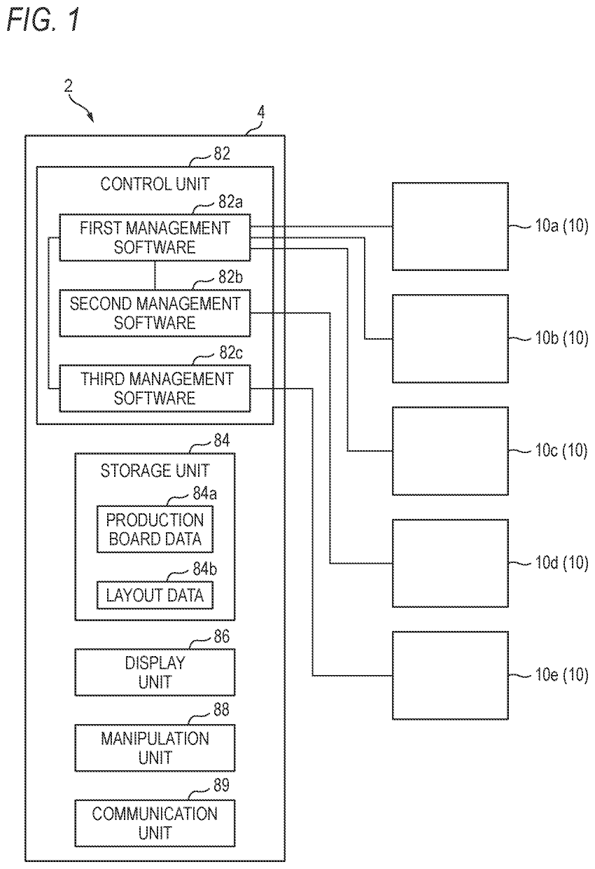

FIG. 1 is a schematic diagram showing a general configuration of a mounting system 2. The mounting system 2 is equipped with a managing apparatus 4 for performing various kinds of management and plural electronic components mounting machines 10 for mounting electronic components on boards. In the embodiment, five electronic components mounting machines 10a, 10b, 10c, 10d, and 10e are provided. The electronic components mounting machines 10a, 10b, 10c, 10d, and 10e will be referred to as electronic components mounting machines 10 if they need not be discriminated from each other. The managing apparatus 4 is connected to the electronic components mounting machines 10 by wire or wirelessly and manages their manufacturing operations.

The managing apparatus 4 shown in FIG. 1 is a computing apparatus such as a personal computer that performs various kinds of information processing according to instructions from an operator, and is equipped with a control unit 82, a storage unit 84, a display unit 86, a manipulation unit 88, and a communication unit 89.

The control unit 82, which is, for example, a CPU (central processing unit), controls operation of the individual units according to manipulations that are input through the manipulation unit 88. The control unit 82 supplies various kinds of information, such as processed information and information stored in the storage unit 84, to the electronic components mounting machines 10 via the communication unit 89. Furthermore, the control unit 82 manages and adjusts manufacturing programs to be supplied to the electronic components mounting machines 10 and controls electronic components mounting operations of the electronic components mounting machines 10. The control unit 82 has first management software 82a, second management software 82b, and third management software 82c for management of the electronic components mounting machines 10. The first management software 82a, second management software 82b, and third management software 82c are programs stored in the storage unit 84.

Each of the first management software 82a, second management software 82b, and third management software 82c generates and optimizes a manufacturing program for a management target electronic components mounting machine(s) 10 and monitors and manages its operation state(s). The first management software 82a, second management software 82b, and third management software 82c are different from each other in information and functions that are set therein and in manageable electronic components mounting machine(s) 10. The first management software 82a, second management software 82b, and third management software 82c are pieces of software that were generated for the same purpose of managing an electronic components mounting machine(s) 10, but were generated at different time points, by different persons, or for different electronic components mounting machines 10.

In the embodiment, the first management software 82a is software that can manage the electronic components mounting machines 10a, 10b, and 10c but does not have the electronic components mounting machines 10d and 10e as management targets. The second management software 82b is software that can manage the electronic components mounting machines 10c and 10d but does not have the electronic components mounting machines 10a, 10b, and 10e. The third management software 82c is software that can manage the electronic components mounting machines 10d and 10e but does not have the electronic components mounting machines 10a, 10b, and 10c.

Management software capable of managing each electronic components mounting machine 10 is set in the control unit 82 as management software for managing it. In the embodiment, for the first management software 82a, the electronic components mounting machines 10a, 10b, and 10c are set as management targets. For the second management software 82b, the electronic components mounting machine 10d is set as a management target. For the third management software 82c, the electronic components mounting machine 10e is set as a management target. Although each electronic components mounting machine 10 communicates with the first management software 82a, the second management software 82b, or the third management software 82c via the communication unit 89, to facilitate understanding of a corresponding relationship between them, each electronic components mounting machine 10 and a corresponding one(s) of the first management software 82a, the second management software 82b, or the third management software 82c are connected by a line in FIG. 1.

In the control unit 82, the first management software 82a is set as master software (main management software) and the second management software 82b and the third management software 82c are pieces of slave software (sub-management software). The first management software 82a sends various kinds of information to the second management software 82b and the third management software 82c and receives various kinds of information from them. Data that are exchanged between the first management software 82a and each of the second management software 82b and the third management software 82c are data of preset items generated in universal form.

Data to be sent from the first management software 82a to each of the second management software 82b and the third management software 82c are data of electronic components to be mounted by each electronic components mounting machine 10, and may be either data indicating relationships between a board, electronic components to be mounted thereon, and mounting positions or data including data (design drawing) indicating mounting states of electronic components on a board to be carried into the electronic components mounting machine 10 and data (design drawing) indicating mounting states of electronic components on a board to be carried out of the electronic components mounting machine 10.

Data to be sent from each of the second management software 82b and the third management software 82c to the first management software 82a are data obtained by extracting prescribed items from results of execution of a manufacturing program. Example items are at least one of the number of feeders and a time relating to manufacture.

The first management software 82a can manage all of the electronic components mounting machines 10 of the mounting system 2 by managing its management target electronic components mounting machines 10 and managing, via the second management software 82b and the third management software 82c, the target electronic components mounting machines 10 being managed by the second management software 82b and the third management software 82c. Thus, the first management software 82a can manage a production line that manufactures boards using plural electronic components mounting machine 10. Each of the first management software 82a, the second management software 82b, and the third management software 82c manages its management target electronic components mounting machine(s) 10 and optimizes manufacture by it. The first management software 82a optimizes manufacture of boards by managing the production line that manufactures boards using the plural electronic components mounting machine 10.

The storage unit 84 is equipped with a primary storage device (main storage device) such as a memory and/or a secondary storage device (auxiliary storage device) such as a storage, and is a RAM (random access memory), a ROM (read-only memory), a semiconductor storage device, or a combination thereof. The storage unit 84 is stored with computer programs for controlling operation of the managing apparatus 4 and various kinds of information. The control device 82 may also be equipped with a primary storage device.

The storage unit 84 is stored with production board data 84a and layout data 84b. Data indicating positions and kinds of electronic components to be mounted are stored for each board to be manufactured as production board data 84a. That is, data of a design drawing indicating what electronic components are to be mounted at what positions on a board are stored for each board to be manufactured as production board data 84a.

Various kinds of design data of each electronic components mounting machine 10 are stored as layout data 84b. More specifically, data indicating positions of component supply units of each electronic components mounting machine 10, member units constituting each component supply unit and their arrangement, distances between the component supply units and board conveying units, positional relationships between the component supply units, the number of nozzles of a head, types of usable nozzles, a shape of a board to be conveyed by the board conveying units, board holding positions during a mounting operation, etc. are stored as layout data 84b. In addition, various conditions of each electronic components mounting machine 10 necessary for setting electronic components holding order and mounting order are stored as production layout data 84b.

The display device 86 is a display device for displaying operation states of individual units of each electronic components mounting machine 10, setting pictures, and information stored in the storage unit 84. The display device 86 displays an image under the control of the control unit 82.

The manipulation unit 88 is an input device through which an operator (user) is to input manipulations, and the manipulation unit 88 sends a manipulation signal indicating an input manipulation to the control unit 82. The manipulation unit 88 may be any of various input devices such as a controller, a manipulation panel, switches, levers, a keyboard, and a mouse. The display device 86 and the manipulation unit 88 may be integrated into a touch panel.

The communication unit 89 is a communication device which sends and receives information to and from the electronic components mounting machines 10. The communication unit 89 is connected to the electronic components mounting machines 10 by wire, that is, by communication lines. The communication unit 89 may be configured so as to be able to communicate with other communication devices, in which case the communication unit 89 can acquire information from various communication devices.

Configured in the above-described manner, the managing apparatus 4 generates a manufacturing program for controlling a mounting operation that each electronic components mounting machine 10 performs to manufacture a board of the production board data 84a as the first management software 82a, the second management software 82b, and the third management software 82c of the control unit 82 performs computation on the basis of the production board data 84a and the layout data 84b stored in the storage unit 84. More specifically, the managing apparatus 4 determines which of electronic components to be mounted on the board of the production board data 84a are to be mounted by each electronic components mounting machine 10, generates manufacturing programs corresponding to respective electronic components mounting machines 10, and provides the generated manufacturing programs for the respective electronic components mounting machines 10. By supplying the generated manufacturing programs to the respective electronic components mounting machines 10, the managing apparatus 4 can set absorption order and mounting order of electronic components for manufacture of the board in each electronic components mounting machine 10.

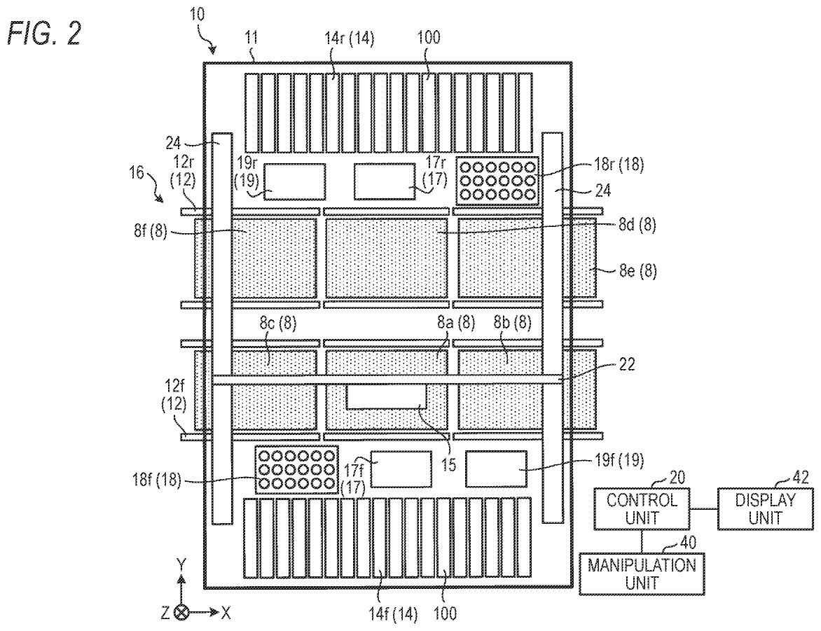

FIG. 2 is a schematic diagram showing a general configuration of each electronic components mounting machine 10. Each electronic components mounting machine 10 will be described below with reference to FIG. 2. The electronic components mounting machine 10 shown in FIG. 2 is a machine for mounting electronic components on boards 8. The electronic components mounting machine 10 is equipped with a chassis 11, board conveying units 12f and 12r, component supply units 14f and 14r, a head 15, an XY moving mechanism 16, VCS units 17f and 17r, nozzle exchangers 18f and 18r, components storage units 19f and 19r, a control unit 20, a manipulation unit 40, and a display unit 42. The XY moving mechanism 16 is equipped with an X-axis drive unit 22 and Y-axis drive units 24. Although in the electronic components mounting machine 10 shown in FIG. 2 the control unit 20, the manipulation unit 40, and the display unit 42 are disposed outside the chassis 11, they may be disposed inside the chassis 11.

As shown in FIG. 2, each electronic components mounting machine 10 used in the embodiment is equipped with the board conveying units 12f and 12r, component supply units 14f and 14r, the VCS units 17f and 17r, the nozzle exchangers 18f and 18r, and the components storage units 19f and 19r. In this manner, the electronic components mounting machine 10 are equipped with several pairs of units. The board conveying unit 12f, the component supply unit 14f, the VCS unit 17f, the nozzle exchanger 18f, and the components storage unit 19f constitute one lane (module) that is disposed on the front side in the electronic components mounting machine 10. And the board conveying unit 12r, the component supply unit 14r, the VCS unit 17r, the nozzle exchanger 18r, and the components storage unit 19r constitute another lane (module) that is disposed on the rear side in the electronic components mounting machine 10.

In the following description, the two board conveying units 12f and 12r will be referred to as board conveying units 12 if they need not be discriminated from each other, the two component supply units 14f and 14r will be referred to as component supply units 14 if they need not be discriminated from each other, the two VCS units 17f and 17r will be referred to as VCS units 17 if they need not be discriminated from each other, the two nozzle exchangers 18f and 18r will be referred to as nozzle exchangers 18 if they need not be discriminated from each other, and the two components storage units 19f and 19r will be referred to as components storage units 19 if they need not be discriminated from each other.

It suffices that the board 8 be a member to be mounted with electronic components, and there are no particular limitations on its structure. In the embodiment, the board 8 is a plate-like member whose surface is formed with wiring patterns. Solder layers which are joining members for joining electronic components to the wiring patterns by a reflow process are attached the surfaces of the wiring patterns formed on the board 8. In FIG. 2, six bards 8, that is, boards 8a, 8b, 8c, 8d, 8e, and 8f are being conveyed by the board conveying units 12f and 12r.

The chassis 11 is a box that houses (incorporates) the units constituting the electronic components mounting machine 10. The front-side component supply unit 14f is disposed on the front side in the chassis 11, and the manipulation unit 40 and the display unit 42 are disposed on the front side of (outside) the chassis 11. The rear-side component supply unit 14r is disposed on the rear side in the chassis 11. The two confronting side walls, not adjacent to the component supply units 14f and 14r, of the chassis 11 are formed with two respective openings through which to carry boards 8 into and out of the electronic components mounting machine 10.

The board conveying units 12 are conveying mechanisms for conveying boards 8 in the X-axis direction (see FIG. 2). The board conveying unit 12f is conveying the boards 8a, 8b, and 8c, and the board conveying unit 12r is conveying the boards 8d, 8e, and 8f. The head 15 mounts electronic components on the surface of a board 8 that is located at a prescribed position. The position where the board 8b is located in FIG. 2 is a prescribed position, for mounting of electronic components by the head 15, of the board conveying unit 12f. The position where the board 8e is located in FIG. 2 is a prescribed position, for mounting of electronic components by the head 15, of the board conveying unit 12r. As soon as electronic components have been mounted on a board 8 located at the prescribed position, the board conveying unit 12 conveys the board to a machine to execute a following process.

The board conveying units 12 may have any of various kinds of conveying mechanisms. Although in the embodiment the two board conveying units 12f and 12r are provided and convey boards 8 separately, the number of board conveying units 12 is not subject to any particular limitations and may be one or larger than three. One board 8 may be conveyed by both of the board conveying units 12f and 12r.

In the electronic components mounting machine 10, the front-side component supply unit 14f is disposed on the front side and the rear-side component supply unit 14r is disposed on the rear side. The front-side component supply unit 14f is equipped with electronic component supply devices 100 each of which holds a large number of electronic components to be mounted on boards 8 and can supply an electronic component to the head 15, that is, can supply an electronic component to a holding position in a state that it can be held (absorbed or gripped) by the head 15. The rear-side component supply unit 14r is equipped with electronic component supply devices 100 each of which holds a large number of electronic components to be mounted on boards 8 and can supply an electronic component to the head 15, that is, can supply an electronic component to a holding position in a state that it can be held (absorbed or gripped) by the head 15. In the embodiment, the component supply units 14f and 14r have the same configuration and they are each equipped with plural electronic component supply devices 100. Each electronic component supply device 100 supplies electronic components to the holding position where the head 15 is to hold an electronic component. The configuration of each component supply unit 14 will be described below.

Each component supply unit 14 is equipped with plural electronic component supply devices (hereinafter referred to simply as component supply devices) 100. The plural electronic component supply devices 100 are held by a support stage (bunk). The support stage can also be mounted with other devices (e.g., a measuring instrument, a camera, or the like).

Each electronic component supply device 100 supplies a chip-type electronic component or an insertion-type electronic component to a holding region (absorption position, gripping position, or holding position). The electronic component that has been supplied from the electronic component supply device 100 to the holding position is held by and mounted on a board 8 by the head 15.

The plural electronic component supply devices 100 may supply different types of electronic components or different sets of electronic components. Each electronic component supply device 100 may be a tape feeder, a stick feeder, a bulk feeder, or a bowl feeder. Example chip-type electronic components (placement-type electronic components) are an SOP and a QFP. Chip-type electronic components are mounted on a board 8 in such a manner as to be placed on its surface. Example insertion-type electronic components are various electronic components having lead wires such as a resistor and a capacitor.

The head 15 is a mechanism for holding (absorbing or gripping) electronic components supplied from the component supply unit 14 (electronic component supply devices 100) by means of nozzles and mounting the electronic components held by itself on a board 8 that has been moved to a prescribed position by one of the board conveying units 12. The head 15 is equipped with plural (e.g., six) nozzles. Tip portions of the nozzles of the head 15 are replaceable and can be replaced so as to be suitable for electronic components to be held (absorbed or gripped).

In the embodiment, the head 15 holds electronic components supplied from the component supply units 14f and 14r and mounts them on the boards 8b and 8e that have been conveyed by the board conveying units 12f and 12r. That is, the head 15 holds electronic components supplied from at least one of the front-side component supply unit 14f and the rear-side component supply unit 14r and mounts them on the boards 8b and 8e. Not only can the head 15 mount electronic components supplied from the component supply unit 14f or 14r on the near-side board 8e or 8e, but also the head 15 can hold electronic components supplied from the front-side component supply unit 14f and mount them on the board 8e in the rear-side module or hold electronic components supplied from the rear-side component supply unit 14r and mount them on the board 8b in the front-side module.

The XY moving mechanism 16 is a moving mechanism for moving the head 15 in the X-axis direction and the Y-axis direction (see FIG. 2), that is, in the plane that is parallel with the surfaces of the boards 8, and is equipped with the X-axis drive unit 22 and the Y-axis drive unit 24. The X-axis drive unit 22 is connected to the head 15 and moves it in the X-axis direction. The Y-axis drive unit 24 is connected to the head 15 via the X-axis drive unit 22, and moves the head 15 in the Y-axis direction by moving the X-axis drive unit 22 in the Y-axis direction. By moving the head 15 in the X-axis direction and the Y-axis direction, the XY moving mechanism 16 can move the head 15 to a position where the head 15 is opposed to the board 8b or 8e or the component supply unit 14f or 14r.

The XY moving mechanism 16 adjusts the position of the head 15 relative to the boards 8 by moving the head 15, whereby an electronic component being held by the head 15 can be moved to any position over the surface of a board 8 and mounted on the surface of the board 8 at that position. As such, the XY moving mechanism 16 is a transferring means for transferring an electronic component supplied from an electronic component supply device 100 of the component supply unit 14f or 14r to a prescribed position (mounting position) on a board 8 by moving the head 15 in the horizontal plane (XY plane).

The X-axis drive unit 22 may be any of various mechanisms for moving the head 15 in a prescribed direction. The Y-axis drive unit 24 may be any of various mechanisms for moving the X-axis drive unit 22 in a prescribed direction. Example mechanisms for moving the head 15 in a prescribed direction are a linear motor, a rack-pinion mechanism, a conveying mechanism using a ball screw, and a conveying mechanism using a belt.

The VCS units 17, the nozzle exchangers 18, and the components storage units 19 are disposed at positions in areas of an XY plane that are included in a movable area of the head 15 in a plan view and at a position in the Z-axis direction that is lower than the head 15. In the embodiment, the VCS unit 17f, the nozzle exchanger 18f, and the components storage unit 19f are arranged adjacent to each other between the board conveying unit 12f and the component supply unit 14f. And the VCS unit 17r, the nozzle exchanger 18r, and the components storage unit 19r are arranged adjacent to each other between the board conveying unit 12r and the component supply unit 14r.

Each VCS unit 17 (component state detection unit, state detection unit) is an image recognition device, and recognizes shapes of the electronic components held by the head 15 and states of holding of the electronic components by the nozzles. Each nozzle exchanger 18 is a mechanism that is equipped with plural kinds of nozzles and replaces nozzles attached to the head 15. Each components storage unit 19 is a box for storing electronic components that were held by nozzles of the head 15 and are not to be mounted on the boards 8.

The control unit 20, which is a collection of various control units, controls the individual units of the electronic components mounting machine 10. The manipulation unit 40 is an input device through which a worker is to input manipulations, and has a keyboard, a mouse, a touch panel, or the like. The manipulation unit 40 sends various kinds of inputs detected to the control unit 20. The display unit 42 is equipped with a touch panel, a vision monitor, or the like and has a screen on which to display various kinds of information to a worker. The display unit 42 displays any of various kinds of images on the touch panel or the vision monitor on the basis of an image signal received from the control unit 20.

Next, a description will be made of how each electronic components mounting machine 10 operates. Operations, described below, of each electronic components mounting machine 10 are each performed as the individual units are controlled by the control unit 20.

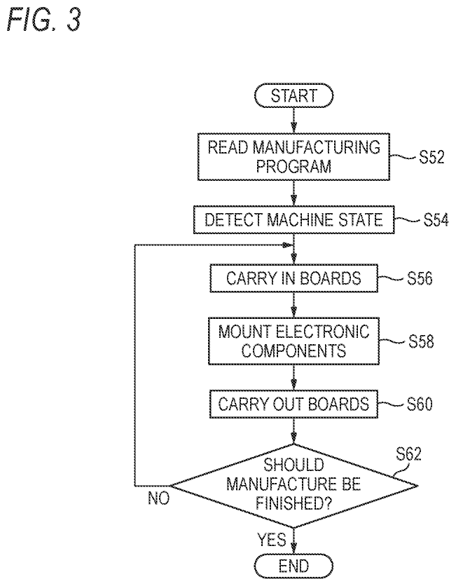

FIG. 3 is a flowchart illustrating an example operation of each electronic components mounting machine 10. An overall process of the electronic components mounting machine 10 will be outlined below, which is executed as the control unit 20 controls the individual units. At step S52, the electronic components mounting machine 10 reads a manufacturing program. The manufacturing program is generated by a dedicated manufacturing program generation device or generated by the control unit 20 on the basis of various kinds of input data.

Upon reading the manufacturing program at step S52, at step S54 the electronic components mounting machine 10 detects a state of itself. More specifically, the electronic components mounting machine 10 detects configurations of the component supply units 14f and 14r, kinds of electronic components that are set therein, kinds of nozzles prepared, etc. Upon detecting a state of the machine 10 at step S54 and completing preparations, at step S56 the electronic components mounting machine 10 carries in boards 8. Upon carrying in boards 8 at step S56 and setting them at positions where to mount electronic components thereon, at step S58 the electronic components mounting machine 10 mounts electronic components on the boards 8. Upon completing the mounting of the electronic components, at step S60 the electronic components mounting machine 10 carries out the boards 8. At step S62, the electronic components mounting machine 10 judges whether the manufacture should be finished.

If judging that the manufacture should not be finished (S62: no), the electronic components mounting machine 10 returns to step S56 to mount electronic components on the boards 8 further according to the manufacturing program at steps S56-S60. If judging that the manufacture should be finished (S62: yes), the electronic components mounting machine 10 finishes the process.

As described above, the electronic components mounting machine 10 can manufacture boards mounted with electronic components by reading a manufacturing program, making various settings, and mounting electronic components on boards 8.

In the mounting system 2, each of plural electronic components mounting machine 10 arranged in line mounts electronic components assigned to it on boards 8. As a result, each board 8 that has passed through the plural electronic components mounting machine 10 becomes a board that is mounted with a variety of electronic components.

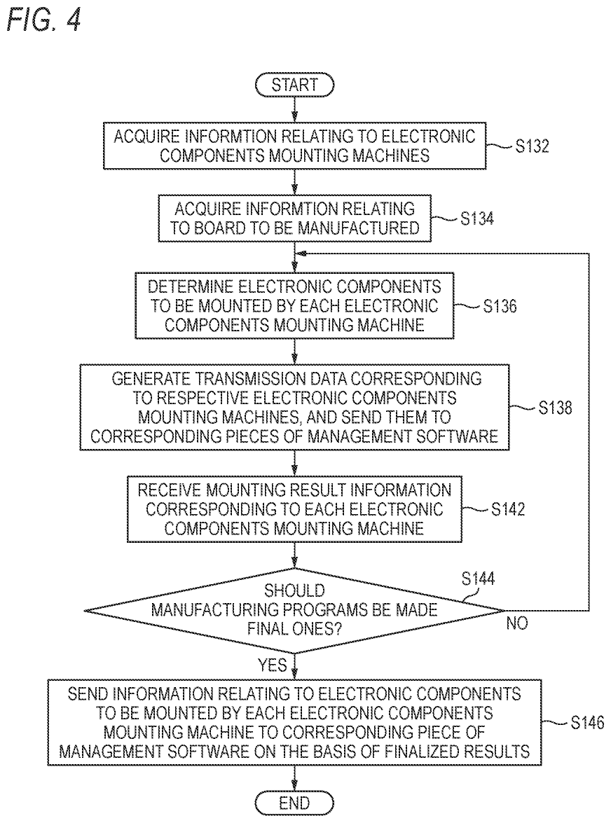

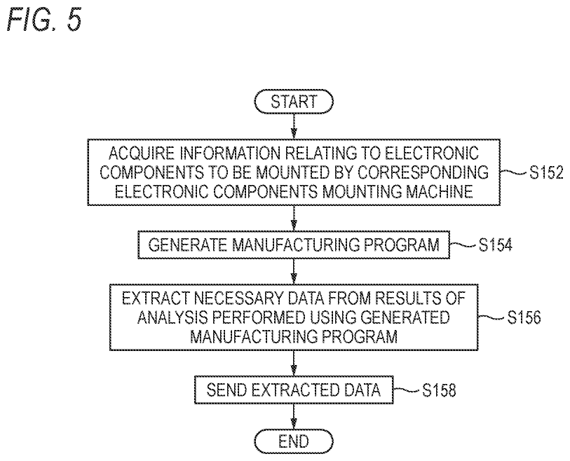

Next, referring to FIGS. 4 and 5, a description will be made of control operations performed by the mounting system 2, more specifically, procedures according to which the managing apparatus 4 generates manufacturing programs. FIGS. 4 and 5 are flowcharts illustrating example operations of the managing apparatus 4.

First, the process shown in FIG. 4 will be described, which is a process that is executed by the first management software 82a which is master software (main management software). The first management software 82a makes settings as to what electronic components mounting machines 10 should be used to mount electronic components to manufacture an intended board and thereby establishes an optimized production line by operating while exchanging information with the second management software 82b and the third management software 82c.

At step S32, the first management software 82a acquires information relating to electronic components mounting machines 10 to constitute a production line. Information relating to the electronic components mounting machines 10 may be acquired either by acquiring data stored in the storage unit 84 or from the electronic components mounting machines 10 via the pieces of management software to manage them. Data of items (e.g., the number of nozzles, the number of feeders, kinds of mountable electronic components) that are set in preset formats are supplied as information relating to each electronic components mounting machine 10.

At step S134, the first management software 82a acquires information relating to the board to be manufactured, that is, information relating to a board 8, electronic components to be mounted on the board 8, and mounting positions of the electronic components. The first management software 82a may execute step S132 and S134 either in parallel or in opposite order.

At step S136, the first management software 82a determines electronic components electronic components to be mounted by each electronic components mounting machine 10 on the basis of the information relating to the electronic components mounting machines 10 and the information relating to the board to be manufactured.

At step S138, the first management software 82a generates transmission data corresponding to each electronic components mounting machine 10. That is, the first management software 82a generates, as transmission data, data of electronic components to be mounted by correlating each electronic components mounting machine 10 with electronic components assigned to it for mounting. The first management software 82a sends the generated transmission data that are information relating to the electronic components to be mounted on a board 8 by each electronic components mounting machine 10 to the second management software 82b or the third management software 82c that has, as a management target, the electronic components mounting machine 10. The first management software 82a sends, to itself, the generated transmission data corresponding to each electronic components mounting machine 10 managed by itself.

Now, the process shown in FIG. 5 will be described, which is a process that is executed by each of the second management software 82b and the third management software 82c which are pieces of slave software (sub-management software). In the following, the process shown in FIG. 5 will be described as a process that is executed by the second management software 82b. The first management software 82a also executes the process shown in FIG. 5 as a process for each management target electronic components mounting machine 10.

At step S152, the second management software 82b acquires information relating to electronic components to be mounted by the corresponding electronic components mounting machine 10 (10d). That is, the second management software 82b acquires information that is sent from the first management software 82a and relates to electronic components to be mounted on the board 8 by its management target electronic components mounting machine 10.

Upon acquiring the information relating to electronic components to be mounted, at step S154 the second management software 82b generates a manufacturing program for causing the management target electronic components mounting machine 10 to mount the electronic components. The second management software 82b extracts necessary data from results of an analysis of mounting performed using the generated manufacturing program at step S156, and sends the extracted data to the first management software 82a at step S158. More specifically, upon generating the manufacturing program, the second management software 82b performs analyzing computation such as a simulation to calculate results of mounting of the electronic components performed using the manufacturing program, extracts necessary information such as a time taken to perform mounting on one board 8, and sends the extracted information to the first management software 82a.

The managing apparatus 4 can cause the first management software 82a (main management software) to execute the remaining part of the process shown in FIG. 4 by causing each of the first management software 82a, the second management software 82b (sub-management software), and the third management software 82c (sub-management software) to generate a manufacturing program(s) for its management electronic components mounting machine(s) 10 and send data of preset items extracted from results of analysis of mounting performed using the generated manufacturing program.

Returning to FIG. 4, at step S142, the first management software 82a receives, as mounting result information corresponding to each electronic components mounting machine 10, data that are sent from each piece of management software by executing the process shown in FIG. 5. That is, the first management software 82a acquires, from each piece of management software, information relating to the items extracted from calculation results of mounting performed using the generated manufacturing program for mounting the electronic components.

At step S144, the first management software 82a analyzes the acquired information and judges whether the current manufacturing programs should be made final ones. If it is judged that the current manufacturing programs should not be made final ones (S144: no), the first management software 82a returns to step S136. The first management software 82a adjusts the electronic components to be mounted by each electronic components mounting machine 10, that is, changes the electronic components to be assigned, for mounting, to each electronic components mounting machine 10, on the basis of the information relating to the acquired items and the information relating to the board to be manufactured.

If it is judged that the current manufacturing programs should be made final ones (S144: yes), at step S146 the first management software 82a sends information relating to the electronic components to be mounted by each electronic components mounting machine 10 to the corresponding piece of management software on the basis of the finalized results. Each piece of management software generates a manufacturing program to be run by (each of) the management electronic components mounting machine(s) 10 on the basis of the information relating to the electronic components to be mounted by it, and sends the generated manufacturing program to the electronic components mounting machine 10. As a result, each electronic components mounting machine 10 is allowed to mount target electronic components. The first management software 82a optimizes the manufacturing programs that are used for manufacturing the board by repeatedly adjusting the electronic components to be mounted by each electronic components mounting machine 10, that is, changing the electronic components to be assigned, for mounting, to each electronic components mounting machine 10, by executing steps S136 to S144.

In the managing apparatus 4, plural pieces of management software are divided into main management software and pieces of sub-management software. Items of information to be exchanged between the pieces of management software are determined in advance, and each electronic components mounting machine is managed by the main management software or sub-management software while overall management is done by the main management software. With this measure, the electronic components mounting machines in a production line can be managed in link with each other even in a case that one piece of management software cannot handle all of the electronic components mounting machines. For example, with latest pieces of management software, even in the case of a production line having an electronic components mounting machine that is not a management target, all of the electronic components mounting machines belonging to the production line can be managed in link with each other by using existing management software as sub-management software. As a result, the number of kinds of electronic components mounting machines to be dealt with by each piece of management software can be reduced, which facilitates the management, maintenance, and development of pieces of management software.

Furthermore, since a new piece of management software can be introduced while pieces of management software capable of managing existing electronic components mounting machines continue to be used, it becomes possible to operate a production line stably. That is, a problem can be prevented that trouble occurs in an existing electronic components mounting machine due to management software switching.

In the managing apparatus 4, it is preferable that each piece of sub-management software monitor a manufacturing operation of its management target electronic components mounting machine and send information extracted from the electronic components mounting machine to the main management software. In the managing apparatus 4, it is also preferable that the main management software monitor the manufacture by its management target electronic components mounting machines and perform management using, in an integral manner, information extracted from its management target electronic components mounting machines and the information acquired from the pieces of sub-management software. More specifically, it is preferable that the main management software display warning information and production result information acquired from the pieces of sub-management software. In this manner, manufacturing operations of electronic components mounting machines that cannot be managed directly by the main management software can be managed by causing the main management software to manage the pieces of sub-management software for a production monitoring job.

Although in the mounting system 2 according to the embodiment the single managing apparatus 4 manages the five electronic components mounting machines 10, the invention is not limited to that case. The managing apparatus 4 may be divided into plural apparatus. More specifically, a mounting system is possible in which separate apparatus run the first management software 82a, the second management software 82b, and the third management software 82c and communicate with each other. Although in the embodiment the managing apparatus 4 is separate from each electronic components mounting machine 10, the managing apparatus 4 may be incorporated in one of the electronic components mounting machines 10. That is, the functions of the managing apparatus 4 may be implemented by units of the electronic components mounting machine 10.

1.-4. (canceled)

5. A managing method that manages a plurality of electronic components mounting machines for mounting electronic components on a board, the method including:
executing main management software that manages at least one electronic components mounting machine of the plurality of electronic component mounting machines; and
executing at least one piece of sub-management software that manages at least another one electronic components mounting machine of the plurality of electronic component mounting machines that is not a management target of the main management software,
wherein the sub-management software:
acquiring, from the main management software, information relating to electronic components to be mounted on the board by the electronic components mounting machine as a management target of the sub-management software;
generating a manufacturing program based on the acquired information relating to electronic components to be mounted on the board;
extracting preset items information from calculation results obtained using the manufacturing program; and
sending the extracted preset items information to the main management software, wherein the main management software:
determining electronic components to be mounted on the board by each of the electronic components mounting machines based on design data of i) a board to be manufactured, ii) a number of nozzles and a number of feeders of each of the electronic components mounting machines, and iii) kinds of mountable electronic components of each of the electronic components mounting machines;
sending information relating to the electronic components to be mounted to the sub-management software or the main management software itself that has, as a management target, the electronic components mounting machine to mount the electronic components;
acquiring the preset items information extracted from calculation results obtained using the manufacturing program for mounting the electronic components and sent from each of the sub-management software and the main management software itself; and
adjusting the electronic components to be mounted by each of the electronic components mounting machines based on the acquired the preset items information and the design data of the board to be manufactured.

6. The managing method according to claim 5, wherein the items include at least one of the number of feeders and a time relating to manufacture.

7. The managing apparatus according to claim 5,
wherein the sub-management software:
monitoring production by its management target electronic components mounting machine; and
sending information extracted from the management target electronic components mounting machine to the main management software, and
wherein the main management software:
monitoring production by its management target electronic components mounting machine; and
managing information extracted from the management target electronic components mounting machine and the information acquired from the sub-management software.

8. The managing apparatus according to claim 6,
wherein the sub-management software:
monitoring production by its management target electronic components mounting machine; and
sending information extracted from the management target electronic components mounting machine to the main management software, and
wherein the main management software:
monitoring production by its management target electronic components mounting machine; and
managing information extracted from the management target electronic components mounting machine and the information acquired from the sub-management software.
